(19) United States
(12) Patent Application Publication
(10) Pub. No.: US 2025/0324645 A1
(43) Pub. Date: Oct. 16, 2025

(54) STRESS TRANSFER LAYER FOR A HIGH ELECTRON MOBILITY TRANSISTOR

(71) Applicant: Indian Institute of Science, Bangalore (IN)

(72) Inventors: Mehak Ashraf MIR, Bangalore (IN); Mayank SHRIVASTAVA, Bangalore (IN)

(21) Appl. No.: 19/177,462

(22) Filed: Apr. 11, 2025

(30) Foreign Application Priority Data
Apr. 12, 2024 (IN) 202441029855

(51) Int. Cl. H10D 30/47; H01L 23/31; H10D 30/01; H10D 62/85; H10D 64/00

(52) U.S. Cl. CPC H10D 30/475; H01L 23/3171; H10D 30/015; H10D 62/8503; H10D 64/111

(57) ABSTRACT

The present disclosure relates to Gallium Nitride (GaN) High Electron Mobility Transistor (HEMT) (100) i.e. a semiconductor device (100) which includes a buffer layer (104) formed on the substrate (120). An unintentionally doped (UID) Gallium Nitride (GaN) channel layer (102) is positioned on the buffer layer (104). A barrier layer (106) is formed on the UID channel layer (102) to enable formation of two-dimensional electron gas (2DEG) at interface between UID GaN channel layer (102) and barrier layer (106). A stress transfer layer (116) having tunable intrinsic compressive mechanical stress is deposited on barrier layer (106) to enhance device performance and reliability. Further, the intrinsic stress in the stress transfer layer (116) is tailored to enhance performance in terms of higher threshold voltage and breakdown voltage, and reliability in terms of reduced dynamic R_{ON} under DC and switching stress and stable threshold voltage under ON and OFF state gate stress.

### RELATED APPLICATIONS

This application claims priority to Indian application Ser. No. 20/244,1029855 filed on Apr. 12, 2024 which is incorporated herein by reference in its entirety.

### TECHNICAL FIELD

The present disclosure relates to a field of material engineering and fabrication of stress transfer layer for high electron mobility transistors. More particularly, the present disclosure relates to mechanical stress-engineered material layer for Gallium Nitride (GaN)-based High Electron Mobility Transistor (HEMT) that also passivates the surface underneath while improving performance metrics like increase in threshold voltage and breakdown voltage, and enhancing gate stability and decreasing dynamic ON-resistance.

### BACKGROUND

Background description includes information that may be useful in understanding the present disclosure. It is not an admission that any of the information provided herein is prior art or relevant to the presently claimed disclosure, or that any publication specifically or implicitly referenced is prior art.

Gallium Nitride (GaN) based High Electron Mobility Transistors (HEMTs) have emerged as highly promising candidates for applications requiring high power and high frequency. However, in high-power conversion scenarios, it becomes imperative for transistors to possess a high positive threshold voltage (V_{TH}) and a high OFF-state breakdown voltage (V_{BR}). Moreover, despite their potential, GaN-based HEMTs encounter significant reliability challenges, particularly evident in the form of increased ON-resistance (R_{ON}) immediately after transitioning from OFF or semi-ON states to the ON-state, a phenomenon known as dynamic R_{ON} (ΔR_{ON}). This increase in dynamic R_{ON} poses a significant obstacle to the widespread adoption of GaN HEMT technology. Additionally, the drift in the threshold voltage of the device under ON and OFF state gate stress is another reliability challenge in GaN HEMTs.

Several design architectures have been proposed for GaN HEMT to have high positive threshold voltage for fail-safe power applications. Among them, p-GaN gate HEMTs is the most preferred architecture due to its potential for industrialization. However, this technology suffers from challenges like high ON-state gate leakage and limited gate over drive on account of strong electric field developed in p-GaN in ON state. Owing to the defects generated in the gate stack due to magnesium out diffusion, p-GaN technology also suffers from threshold voltage instability under ON and OFF state gate stress. Thus, there is a need in the industry for a technology solution to solve all these challenges.

In an ideal power semiconductor device, the device breakdown may occur as the channel electric field crosses a certain value leading to the impact ionization followed by carrier multiplication. In GaN HEMT, non-uniform distribution of electric field can lead to field crowding and ultimately a pre-mature device breakdown. For better distribution of channel electrical field, several configurations of field plates in addition to introducing acceptor type doping in buffer have been implemented that redistribute the field in the gate to drain access region. However, to further push the limits of GaN technology for higher power conversions, better field management with simple design techniques are needed.

Moreover, various prior arts have also explored the factors contributing to the rise in R_{ON}, attributing it primarily to trapping phenomena occurring within the buffer and/or at the surface of the barrier layer of the device. Consequently, there have been proposals advocating for different surface passivation strategies to mitigate the adverse effects of ΔR_{ON} to some extent. Buffer engineering through doping control, multilayer buffer stacks, buffer-free stacks, Al(Ga)N back barriers, are few other solutions that have been suggested to address the crucial problem of dynamic R_{ON}, which limits the device reliability. However, the issue of increased ON resistance still persists and needs better technological solutions.

Considering all these performance and reliability challenges in the existing GaN HEMT technology, there is a need for a universal design technique that can enhance the device performance as well as improve the device reliability.

The technology solution so developed must reduce the process complexity along with being cost effective.

### OBJECTS OF THE PRESENT DISCLOSURE

Some of the objects of the present disclosure, which at least one embodiment herein satisfies are as listed herein below.

An object of the present disclosure is to provide a semiconductor device with an improved stress transfer layer configuration to improve device performance and reliability.

It is another object of the present disclosure to provide a GaN-based semiconductor device, such as a High-Electron-Mobility Transistor (HEMT), that integrates a stress transfer layer whose intrinsic mechanical stress can be engineered to a desired compressive value for improving performance and reliability of the device.

In another object of the present disclosure to provide a stress transfer layer that transfers the mechanical stress to the nearby regions while passivating the surface underneath.

Yet another object of the present disclosure is to provide a compressive stress transfer layer that improves device reliability and performance by shifting peak electric field from an edge of a field plate associated with a gate structure to an edge of a drain contact, thereby mitigating hot-spot formation and early OFF-state breakdown risks.

Yet another object of the present disclosure is to configure compressive stress in the stress transfer layer to increase a threshold voltage of the device, further facilitating a normally-off operation.

Another object of the present disclosure is to provide a stress transfer layer that results in a stable threshold voltage under ON and OFF state gate stress under DC and pulsed conditions, thereby improving the gate reliability of the device.

Another object of the present disclosure is to provide a mechanically compressive stress transfer layer that mitigates dynamic ON resistance under DC and pulsed stress conditions. Additionally, the stress transfer design may improve the dynamic performance even under real time switching conditions.

Other objects and advantages of the present disclosure will be more apparent from the following description, which is not intended to limit the scope of the present disclosure.

### SUMMARY

Within the scope of this application, it is expressly envisaged that the various aspects, embodiments, examples, and alternatives set out in the preceding paragraphs, in the claims and/or in the following description and drawings, and in particular the individual features thereof, may be taken independently or in any combination. Features described in connection with one embodiment are applicable to all embodiments unless such features are incompatible.

Aspects of the present disclosure relate to material engineering and fabrication of surface stress transfer layer for high electron mobility transistors (HEMTs). More particularly, the present disclosure relates to mechanical stress-engineered material layer for Gallium Nitride (GaN)-based High Electron Mobility Transistor (HEMT) that also passivates the surface underneath while improving performance metrics like increase in threshold voltage and breakdown voltage, and enhancing gate stability and decreasing dynamic ON-resistance.

In an aspect, the present disclosure may introduce the stress transfer layer with tunable compressive intrinsic stress for a GaN-based HEMT to enhance the performance and reliability of the GaN-based HEMT. The stress transfer layer is configured on the barrier layer of the GaN-based HEMT. The stress transfer layer transfers the mechanical stress to the nearby regions while passivating the surface of the barrier layer underneath. The stress transfer layer is positioned between the source contact and the drain contact of the GaN-based HEMT. The gate structure may consist of a metal stack, with or without a p-type layer, or a dielectric layer sandwiched in between gate metal and barrier layer. The barrier may be on the GaN channel of the HEMT creating a 2-dimensional electron gas (2DEG) channel at the interface between the barrier layer and the GaN channel layer. The GaN channel may be on the buffer layer of the HEMT and the buffer layer of the HEMT may further be on the substrate.

The stress transfer layer may improve the HEMT device's threshold voltage, off-state breakdown voltage, dynamic ON resistance behavior, and threshold voltage stability. An increase in the compressive intrinsic stress in the stress transfer layer may result in the enhancement of the threshold voltage and the OFF-state DC breakdown voltage. The reliability of the GaN-based HEMT device in terms of dynamic R_{ON} under DC stress, under hard switching stress and threshold voltage stability under ON and OFF state gate stress may be improved. The higher compressive stress of the stress transfer layer may result in reduced dynamic ON resistance under OFF state DC stress from ˜1000% to ˜12%. Additionally, an increase in the compressive stress in stress transfer layer may lead to improved reliability under hard switching stress and may present a switching frequency independent dynamic R_{ON}. Moreover, the threshold voltage in GaN-based HEMT with higher compressive stress in stress transfer layer may not drift by more than 100 mV even after 1000 s of ON state gate stress of 7 Volts or OFF state gate stress of −3 Volts, thereby providing higher gate stability as well.

In another aspect, the increase in the compressive stress in the stress transfer layer may result in the electric field peak shifting from the gate field plate edge to the drain edge. The resulting field modulation may increase the OFF-state breakdown voltage of the device as the compressive stress increases in the stress transfer layer.

In another aspect, the increase in compressive stress may result in a positive shift in the threshold voltage, further facilitating the normally-off operation of the HEMT device. Further, the compressive stress in stress transfer may result in a stable V_{TH} under ON and OFF state gate stress under DC and pulsed conditions, thereby demonstrating improved gate reliability.

In another aspect, the increase in compressive stress in stress transfer layer may result in the suppression of dynamic R_{ON} under hard switching stress. It may also result in switching frequency independent dynamic R_{ON} behavior of the HEMT device making the device more suitable for power conversion at higher frequencies.

In yet another aspect, the performance, and reliability of the HEMT device may depend on the stress transfer layer thickness as the intrinsic mechanical stress in stress transfer layer is also a function of the stress transfer layer thickness. The design of the device may consider the co-design of various field plates and stress transfer layer thickness to tune intrinsic mechanical stress in stress transfer layer, to optimize the channel electric field, and thereby, enhance the device performance and reliability.

In such aspect, the stress transfer layer may be formed on the barrier layer. The stress transfer layer may be configured with an intrinsic compressive stress to modulate the electric field distribution in the semiconductor device. The mechanical stress in the stress transfer layer may contribute to optimizing the device performance by improving electric field control, enhancing breakdown voltage, and stabilizing threshold voltage. The fabrication approach may be applicable to high-electron-mobility transistors and other semiconductor devices requiring optimized electric field management that improves device reliability.

Various objects, features, aspects, and advantages of the inventive subject matter will become more apparent from the following detailed description of preferred embodiments, along with the accompanying drawing figures in which like numerals represent like components.

### BRIEF DESCRIPTION OF DRAWINGS

The accompanying drawings are included to provide a further understanding of the present disclosure and are incorporated in and constitute a part of this specification. The drawings illustrate exemplary embodiments of the present disclosure and, together with the description, serve to explain the principles of the present disclosure.

FIG. 1(A) illustrates a schematic cross-sectional view of a high electron mobility transistor (HEMT) with the stress transfer layer whose intrinsic mechanical stress can be tuned for improved device performance and reliability, in accordance with an embodiment of the present disclosure.

FIG. 1(B) illustrates a flow chart of the fabrication process of the proposed semiconductor device having stress transfer layer with tunable intrinsic compressive stress, in accordance with an embodiment of the present disclosure.

FIGS. 2(A) to 2(C) illustrate graphical representations comparing the transfer characteristics, OFF-state breakdown voltage, and Dynamic R_{ON} under DC OFF-state drain stress, of the devices with more compressive stress and less compressive stress in stress transfer layer, respectively, in accordance with an embodiment of the present disclosure.

FIGS. 3(A) to 3(B) illustrate graphical representations comparing the average Electro-luminescence (EL) intensity across the length of the device under semi-ON stress at different drain voltages (V_{DS}) for devices with less compressive stress and more compressive stress in stress transfer layer, respectively, in accordance with an embodiment of the present disclosure.

FIG. 4(A) illustrates a graphical representation of the dynamic R_{ON} characteristics of a device with less compressive stress transfer layer for different gate to drain distance (L_{GD}) in accordance with an embodiment of the present disclosure.

FIG. 4(B) illustrates a graphical representation of the dynamic R_{ON} characteristics of device with more compressive stress transfer layer, for different substrate bias voltages (V_{sub}) in accordance with an embodiment of the present disclosure.

FIG. 4(C) illustrates a graphical representation of the evolution of Electro-luminescence spectra collected from the drain edge for the device with more compressive stress transfer layer in accordance with an embodiment of the present disclosure.

FIGS. 5(A) to 5(B) illustrate graphical representations describing the comparison of the threshold voltage drifts in response to ON state gate stress for devices with less and more compressive stress in the stress transfer layer respectively, in accordance with an embodiment of the present disclosure.

FIGS. 5(C) illustrate a graphical representation describing the comparison of the threshold voltage drifts in response to OFF state gate stress for devices with less and more compressive stress in the stress transfer layer respectively, in accordance with an embodiment of the present disclosure.

FIGS. 6 (A) to 6 (B) illustrate exemplary implementations of a switching circuit and turn ON transition of the HEMT device through hard switching, in accordance with an embodiment of the present disclosure.

FIG. 7 (A) illustrate exemplary graphical representations of the dynamic R_{ON} of the HEMT device under hard switching stress with different compressive mechanical stress in the stress transfer layer, in accordance with an embodiment of the present disclosure.

FIGS. 7(B-C) illustrate exemplary graphical representations of the dynamic R_{ON} of the HEMT device under hard switching stress at different switching frequencies with less and more compressive mechanical stress in the stress transfer layer respectively, in accordance with an embodiment of the present disclosure.

FIGS. 8 (A-C) illustrates an exemplary representation of the design variations in the gate structure that includes a p-type gallium nitride (p GaN) or any p-type oxide like copper oxide (CuO), Nickel oxide (NiO), the semiconductor device that includes a gate dielectric layer like Silicon oxide (SiOₓ), Silicon nitride (SiNₓ), Aluminium oxide (AlOₓ) or any combination thereof, the semiconductor that excludes any p-type layer or dielectric layer in the gate structure, in accordance with an embodiment of the present disclosure.

FIGS. 9 (A-C) illustrates an exemplary representation of the design variations of the field plate in the semiconductor device which is connected to gate metal (A), or connected to drain contact (B), or connected to source contact (C) or may be any combination of these designs, in accordance with an embodiment of the present disclosure.

FIG. 10 (A) illustrates an exemplary representation of the multi-channel HEMT wherein the stress transfer layer is disposed between source and drain contacts, in accordance with an embodiment of the present disclosure.

FIG. 10(B) illustrates an exemplary representation of the schottky barrier diode wherein the stress transfer layer is disposed on the barrier layer, in accordance with an embodiment of the present disclosure.

FIG. 10(C) illustrates the vertical Schottky junction barrier diode wherein the Schottky metal is disposed on the n doped GaN layer, in accordance with an embodiment of the present disclosure.

Skilled artisans will appreciate that elements in the drawings are illustrated for simplicity and have not necessarily been drawn to scale. For example, the dimensions of some elements in the drawings may be exaggerated relative to other elements to help improve understanding of embodiments of the present disclosure.

### DETAILED DESCRIPTION

The one or more shortcomings of the prior art are overcome by the system as disclosed, and additional advantages are provided through the provision of the system as disclosed in the present disclosure. Additional features and advantages are realized through the techniques of the present disclosure. Other embodiments and aspects of the disclosure are described in detail herein and are considered a part of the disclosure.

Herein, the terms “attached”, “connected”, “interconnected”, “contacting”, “mounted”, “coupled” and the like can mean either direct or indirect attachment or contact between elements unless stated otherwise.

Well-known functions or constructions may not be described in detail for brevity and/or clarity. As used herein the expression “and/or” includes any and all combinations of one or more of the associated listed items.

The terminology used herein is for the purpose of describing particular embodiments only and is not intended to be limiting to the disclosure. As used herein, the singular forms “a”, “an” and “the” are intended to include the plural forms as well, unless the context clearly indicates otherwise. It will be further understood that the terms “comprises”, “comprising”, “includes” and/or “including” when used in this specification, specify the presence of stated features, operations, elements, and/or components, but do not preclude the presence or addition of one or more other features, operations, elements, components, and/or groups thereof. The present embodiment relates to a field of material engineering and fabrication of stress transfer layer for high electron mobility transistors. More particularly, the present embodiment relates to mechanical stress-engineered material layer for Gallium Nitride (GaN)-based High Electron Mobility Transistor (HEMT) that also passivates the surface underneath while improving performance metrics like increase in threshold voltage and breakdown voltage and enhancing gate stability and decreasing dynamic ON-resistance. According to an embodiment, the disclosure may be a stress transfer layer 116 for a GaN-based HEMT 100 (terms “HEMT”, “GaN-based HEMT”, “device” and “semiconductor device” are used interchangeably hereinafter) whose intrinsic mechanical stress is engineered to enhance the performance and reliability of the GaN-based HEMT device 100. Stress transfer layer 116 can be configured on the barrier layer 106 of the HEMT device 100 such that barrier layer 106 can be on the GaN channel layer 102 of the HEMT device 100. Moreover, the GaN channel layer 102 can be on buffer layer 104 of the HEMT device 100 and the buffer layer 104 can be on the substrate 120 of the HEMT 100. Stress transfer layer 116 may be positioned between source contact 112 (terms source contact and source region are used interchangeably hereinafter) and drain contact 114 (terms drain contact and drain region are used interchangeably hereinafter) of the GaN-based HEMT device 100. The HEMT device 100 may include either gate field plate (118) or a drain field plate (118-2) or source field plate (118-1) or any combination thereof to redistribute the electric field in the GaN channel layer 102 of the HEMT device 100. The benefit is an increase in the OFF-state breakdown voltage and a reduced high-field trapping effect. Gate structure may consist of a metal layer 110 forming a Schottky or ohmic contact with barrier layer 106, with or without p-type layer or a dielectric layer 108-1 sandwiched in between the gate metal layer 110 and the barrier layer 106.

The intrinsic stress of the stress transfer layer 116 may be measured on a 3-inch Silicon wafer using the wafer curvature technique. The modulation of intrinsic mechanical stress in the stress transfer layer 116 may be achieved while maintaining the quality of the stress transfer layer 116 with an electrical breakdown field of around 8 MV/cm. The desired magnitude of the compressive stress in the stress transfer layer can lie in the range of −70 MPa to −1 GPa (negative sign indicating a compressive stress). An increase in the compressive stress beyond −1 GPa can lead to delamination of the stress transfer layer and hence can fail the purpose of incorporating this stress engineered layer.

The stress-engineered stress transfer layer 116 can improve the HEMT's threshold voltage and off-state breakdown voltage.

The reliability of the GaN-based HEMT device 100 in terms of dynamic R_{ON} under DC stress, under real-case hard switching stress and threshold voltage stability under ON and OFF state gate stress may be improved. The higher compressive stress of the stress transfer layer 116 may result in reduced dynamic ON resistance under OFF state DC stress from ˜1000% to ˜12%.

In an embodiment, the increase in the compressive stress in the stress transfer layer 116 may result in the electric field peak shifting from the edge of gate field plate 118 to the edge of drain contact 114. The resulting field modulation may increase the OFF-state breakdown voltage of the device 100 by more than 100V as the compressive stress increases in the stress transfer layer 116.

In an embodiment, the increase in compressive stress in stress transfer layer 116 may result in a positive shift in the threshold voltage, further facilitating the normally-off operation of the HEMT device 100. Stress transfer layer 116 with intrinsic stress of higher compressive value may result in more than 500-mV positive shift in threshold voltage.

In an embodiment, increasing the compressive stress in stress transfer layer 116 may result in a stable V_{TH} under ON and OFF state gate stress under DC and pulsed conditions, thereby, demonstrating improved gate reliability. Moreover, the threshold voltage in GaN-based HEMT 100 with higher compressive stress in the stress transfer layer may not drift by more than 100 mV even after 1000 seconds of ON state gate stress of 7 Volts or OFF state gate stress of −3 Volts, thereby providing higher gate stability as well.

In an embodiment, the increase in compressive stress in stress transfer layer 116 may result in the suppression of dynamic R_{ON} under hard switching stress. It may also result in switching frequency independent dynamic R_{ON} behavior of the HEMT device 100 which makes the HEMT 100 suitable for high frequency power conversions.

In an embodiment, the performance, and reliability of the HEMT device 100 can depend on the thickness of the stress transfer layer 116 since the intrinsic mechanical stress is also a function of the stress transfer layer 116 thickness. The design of the device 100 can consider the co-design of field plate 118 and the stress transfer layer 116 thickness to tune intrinsic mechanical stress in stress transfer layer 116, to optimize the channel electric field, and thereby, enhance the HEMT device's 100 performance and reliability.

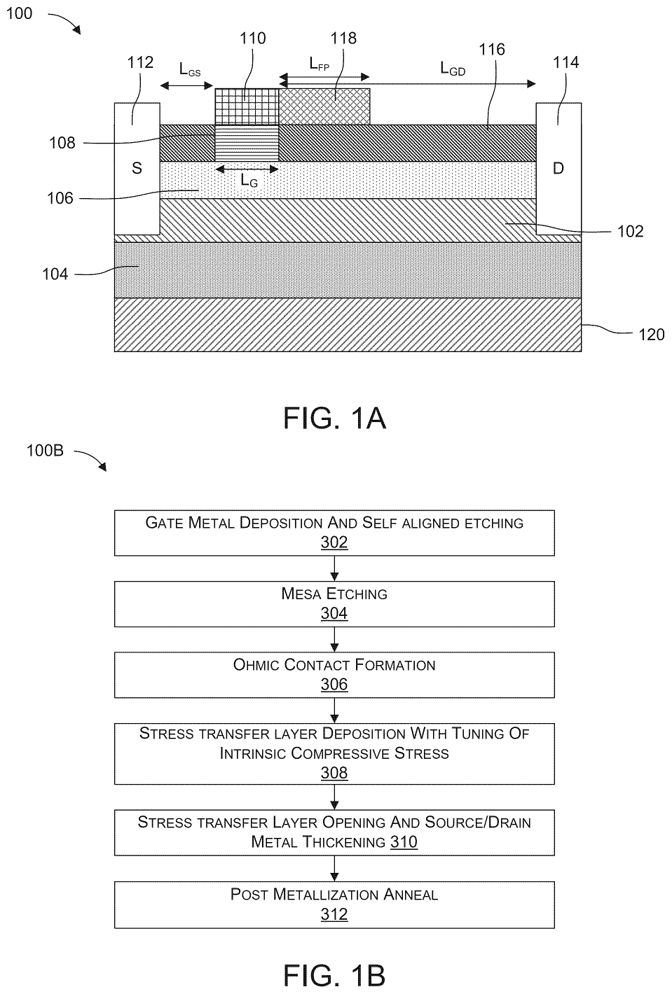

FIG. 1(A-B) illustrates exemplary representations (of a schematic cross-sectional view of a stress transfer layer for a high electron mobility transistor (HEMT) device 100, and a flow chart 100B of the fabrication process of the proposed semiconductor device having stress transfer layer with more intrinsic compressive stress, in accordance with an embodiment of the present disclosure.

Referring to FIG. 1(A) (100), the HEMT device 100 can be fabricated on a commercial grade 600V GaN on-Si wafer with cross-sectional schematic shown in FIG. 1(A).

In an embodiment, the semiconductor device 100 can include a substrate 120. The substrate 120 can be composed of any or a combination of Silicon (Si), Silicon Carbide (SiC), sapphire, diamond, and Qromis Substrate Technology (QST), which are selected based on parameters such as lattice mismatch, thermal conductivity, and mechanical strength.

A buffer layer 104 can be formed directly on the substrate 120. The buffer layer 104 can be a carbon-doped buffer, an iron-doped buffer, or a carbon and iron co-doped buffer. The buffer layer 104 serves to accommodate lattice mismatches between the substrate 120 and the subsequent epitaxial layers, and it also helps in reducing dislocations and other crystalline defects. The inclusion of carbon, iron, or both dopants can improve the electrical isolation and suppress the vertical parasitic conduction pathways, which contributes to enhanced device reliability and high breakdown performance.

Further, an unintentionally doped (UID) Gallium Nitride (GaN) channel layer 102 is positioned on the buffer layer 104. The UID GaN channel layer 102 refers to a semiconductor layer grown without intentional addition of dopants during the epitaxial growth process. The UID GaN channel layer 102 provides a high-mobility channel for electron transport, and due to the absence of deliberate doping, the channel retains superior electron mobility and reduced scattering from ionized impurities.

A barrier layer 106 can be formed on the UID GaN channel layer 102. The barrier layer 106 enables the formation of a two-dimensional electron gas (2DEG) at the heterointerface between the barrier layer 106 and the UID GaN channel layer 102. This 2DEG arises due to polarization effects in materials with wide bandgaps and high spontaneous polarization, allowing high-density electron confinement at the interface without the need for doping. The barrier layer 106 can include a material selected from one or a combination of aluminium gallium nitride (AlGaN), Indium nitride (InN), Indium aluminium nitride (InAlN), or aluminium nitride (AlN). These materials are known to exhibit strong polarization characteristics, thereby facilitating the generation of 2DEG.

A stress transfer layer 116 can be deposited on the barrier layer 106. The stress transfer layer 116 can be configured with a tunable intrinsic compressive mechanical stress. By tuning the compressive stress, it is possible to optimize the performance parameters such as threshold voltage, device breakdown voltage, and improve the device 100 reliability.

Further, the stress transfer layer (116) is made of a dielectric material of any stoichiometry and can include but not limited to, Silicon oxide (SiOₓ), or Silicon nitride (SiNₓ), aluminium oxide (AlOₓ), Hafnium oxide (HfOₓ), zirconium oxide (ZrOₓ), Titanium oxide (TiOₓ), Tantalum oxide (TaOₓ), any p-type oxide like Nickel oxide (NiOₓ), copper oxide (CuO), and Aluminium titanium oxide (AlₓTi₁₋ₓO) and wherein the intrinsic stress in the stress transfer layer (116) is tuned by varying a set of deposition parameters selected from any or a combination of gas flow rate, deposition pressure, deposition power, deposition temperature in the inductively coupled plasma chemical vapor deposition (ICPCVD), or plasma enhanced chemical vapor deposition (PECVD) of the stress transfer layer (116), to achieve the desired mechanical and electrical properties. The desired value of the compressive stress in the stress transfer layer can lie in the range of −70 Mpa to −1 GPa (negative sign indicating a compressive stress).

A gate structure can be positioned over the barrier layer 106, aligned between the source region 112 and the drain region 114. Further, the gate structure includes a metal layer (110). The metal layer (110) can include but not limited to, a titanium (Ti), a titanium nitride (TiN) material, or tungsten (W), tantalum (Ta), Molybdenum (Mo), tantalum nitride (TaN), Scandium (Sc), Nickel (Ni), Chromium (Cr), Gold (Au), and the like. The gate structure further can include but not limited to, p-type material like p-type GaN layer (p-GaN) 108 or any p-type oxide like Nickel oxide (NiO), Titanium oxide (TiO) or any dielectric material 108-1, like Aluminium oxide (AlOx), Silicon oxide (SiOx), or Silicon Nitride (SiNx). In one embodiment, the gate structure may exclude the p-type 108 or dielectric layer 108-1 in gate structure wherein the gate metal layer (110) makes either an ohmic or a Schottky contact with the barrier layer (106).

Further, a field plate 118 can extend from the gate metal layer 110 toward the drain region 114, defined by a gate field plate length L_{FP}. The gate field plate 118 serves to distribute the electric field more uniformly across the channel 102 and reduces peak field concentrations, which is essential for enhancing the breakdown voltage and reducing charge trapping effects.

The source region 112 and the drain region 114 can be electrically connected to the channel layer 102 through respective ohmic contacts. The lateral spacing between the source region 112 and the gate structure is indicated as Los, while the spacing between the gate metal layer 110 and the drain region 114 is shown as L_{GD}. The precise engineering of the distances L_{GS}, L_{G}, L_{FP}, and L_{GD} contributes to optimizing the device's electrical characteristics such as ON resistance, and breakdown voltage.

The structural configuration as illustrated in FIG. 1A allows for the implementation of high-performance semiconductor device 100 suitable for high-frequency and high-power electronic applications.

In another embodiment, the semiconductor device 100 is an GaN based heterostructure can include but not limited to, any of High-Electron-Mobility Transistor (HEMT), Multi-channel HEMTs, Fin channel HEMTs, MIS-HEMTs, Gate injection transistors, Schottky Barrier Diode, Junction Barrier Diode, Fin diodes, multi-channel diodes and monolithic integrated AlGaN/GaN heterostructure.

In another embodiment, the semiconductor device 100 can include a field plate (FP) comprising of the metal layer connected to gate metal layer 110 (gate field plate) 118 or drain contact 114 (drain field plate) 118-2, or source contact 112 (source field plate) 118-1 or any combination thereof.

Further, the fabrication process flow is illustrated in FIG. 1 (B) 100B. A method 100B of fabricating the semiconductor device 100 can include sequential process steps commencing with gate metal deposition 302 and concluding with post metallization anneal 312. The semiconductor device 100 can be fabricated using a gate-first process technique wherein a gate structure is initially formed by depositing a gate metal stack 110. The gate metal stack 110 can include titanium (Ti) or titanium nitride (TiN) materials. The gate metal stack 110 can be deposited over a gate dielectric layer 108-1 or a p-type Gallium Nitride (p-GaN) layer 108. The gate dielectric layer 108-1 or the p-GaN layer 108 can be situated on an Aluminum Gallium Nitride (AlGaN) barrier layer 106. The Ti or TiN gate metal layer 110 can be placed on the gate dielectric layer 108-1 or p-GaN layer 108 to serve as the primary gate electrode.

Subsequent to the gate metal stack 110 deposition, self-aligned etching can be performed to etch the underlying gate dielectric 108-1 or p-GaN layer 108. This is followed by etching step 304 referred as Mesa etching for achieving device isolation between adjacent transistors. Mesa isolation can be implemented to physically separate the active regions of individual devices fabricated on a single wafer. The isolation can be essential in ensuring minimal interference and leakage current between neighbouring devices.

Following the isolation process, ohmic contact formation 306 can be executed to establish electrical connections to the source contact 112 and the drain contact 114. The ohmic contacts can be formed by depositing a metal stack, which can include one or more metallic layers such as but not limited to, titanium (Ti), tantalum (Ta), titanium nitride (TiN), aluminum (Al), nickel (Ni), platinum (Pt), palladium (Pd), molybdenum (Mo), and gold (Au). The metal stack can then undergo an annealing process to create low-resistance contacts to the underlying semiconductor layers.

The stress transfer layer 116 with intrinsic compressive mechanical stress can be deposited using a chemical vapor deposition (CVD) technique at step 308. The intrinsic stress within the stress transfer layer 116 can be tuned by adjusting specific CVD parameters such as gas flow rates, chamber pressure, deposition power, and deposition temperature. The stress transfer layer 116 can be deposited in the access regions on top of the barrier layer 106. The intrinsic stress in the deposited stress transfer layer 116 can be tuned to enhance the performance, reliability and stability of the semiconductor device 100 during operation.

Etching process 310 can then be conducted to open windows in the stress transfer layer 116 at the locations corresponding to the source contact 112, drain contact 114, and the gate metal layer 110. The step 310 can facilitate the formation of electrical interconnections by exposing the metal contact areas. Following the stress transfer opening, additional metal deposition can be performed to thicken the source contact 112 and drain contact 114 metal contacts. During this thickening process 310, a field plate 118 can be simultaneously formed. The field plate 118 can include a Ni/Al/Ni/Au metal stack, which can help manage electric field distribution across the device 100 and improve breakdown voltage and reliability. The field plate 118 can be configured to be connected to the gate metal layer 110, source contact 112 (source field plate 118-1), drain contact 114 (drain field plate 118-2), or any combination thereof, depending on the required device characteristics and design configuration.

Finally, the step 312 in the fabrication process can include a post metallization anneal, which can be conducted in a vacuum environment at a low temperature of approximately 250° C. for a duration of about one hour. The annealing process 312 can stabilize the metal layers and improve contact resistivity and overall device performance.

Alternatively, the semiconductor device 100 can be fabricated using a gate-last process sequence, wherein the gate metal layer 110 deposition is carried out after the stress transfer layer deposition and contact formation steps.

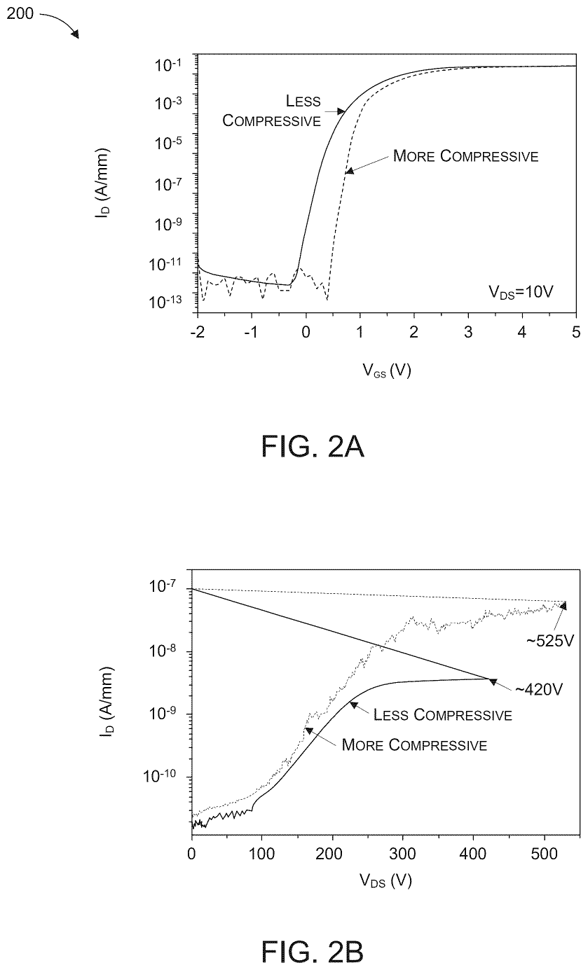

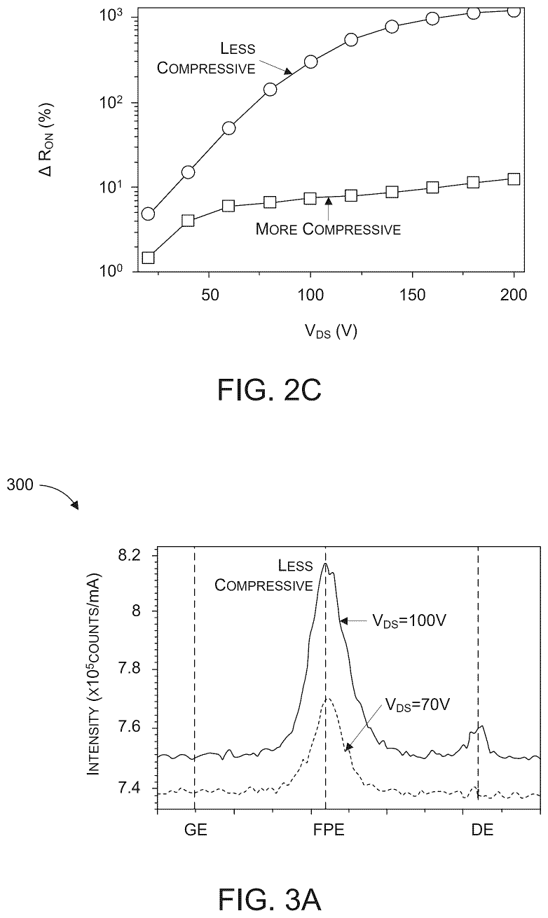

FIGS. 2(A) to 2(C) illustrate a graphical representation 200 that illustrates comparison of the transfer characteristics, OFF-state breakdown voltage, and Dynamic R_{ON} under DC OFF-state drain stress, of the devices with more compressive stress in the stress transfer layer and less compressive stress in the stress transfer layer respectively, in accordance with an embodiment of the present disclosure.

Referring to FIGS. 2(A), the transfer characteristics of the devices may depict excellent device behavior with very low I_{OFF} (˜10⁻¹² A/mm), high I_{ON}/I_{OFF} (˜10¹⁰), and a normally OFF operation. A device with more compressive stress in the stress transfer layer 116 showed a V_{TH}˜500 mV higher than device with lesser compressive stress in the stress transfer layer 116, establishing a positive shift in V_{TH} with an increase in intrinsic compressive stress in the stress transfer layer 116. However, the change in the intrinsic stress of the stress transfer layer 116 may not affect the I_{OFF}. As shown in FIG. 1(A), the gate structure comprises of gate metal layer 110 and a p-GaN layer 108 or a p-type oxide 108 or a dielectric layer 108-1 or any combination thereof. The surface stress transfer layer 116 may cover the sidewalls of the gate structure. This interface of the gate structure to the stress transfer layer 116 may thereby be considered responsible for the observed V_{TH} shift. This may further establish that the mechanical stress in the stress transfer layer may modulate the charges in gate structure and has therefore the potential to modulate gate reliability as well.

Furthermore, the OFF-state breakdown voltage of the HEMT device 100 as shown in FIG. 2(B) may disclose an improvement of ˜105 V with less compressive stress in the stress transfer layer 116 having V_{BD}=420V when compared to device with more compressive stress in the stress transfer layer 116 with V_{BD}=525V. The difference may be understood when semi-ON state electroluminescence (EL) may be carried out to estimate the electric field distribution, as exemplary shown in FIGS. 3 (A-B) 300. For devices with less compressive stress in the stress transfer layer 116, the EL intensity peak may be observed near the edge of the gate field plate (FPE) 118, which may be increased with increase in applied drain bias (V_{DS}). On the other hand, the device with more compressive stress in the stress transfer layer 116 showed a high EL intensity peak only near the drain contact 114 edge (DE) (with no such peak near the edge of the gate field plate 118 even for very low V_{DS}, which may be increased upon the increase in the V_{DS}. This may explain the improved breakdown voltage in HEMT device 100 with more compressive stress in the stress transfer layer 116 on account of its better channel electric field distribution.

Referring to FIG. 2(C), which describes the dynamic R_{ON} of the HEMTs 100 under test as a function of drain stress voltage (V_{DS}) for an OFF-state stress time of 100 ms. The FIG. 2(C) may depict the ΔR_{ON} behavior of devices with more and less compressive stress transfer layer. The HEMT device 100 with more compressive stress transfer layer 116 may show a much lower ΔR_{ON} as compared to HEMT device 100 with less compressive stress transfer layer 116. The higher EL intensity near the gate field plate 118 edge for HEMT with less compressive stress transfer layer 116 may result in electron injection and trapping in the buffer layer 104, or it may also lead to hole emission. The field intensity near the gate field plate 118 edge and edge of gate structure (GE) may be reduced with an increase in the gate-to-drain distance (L_{GD}) which may reduce electron injection and trapping near the gate field plate edge 118, and hence the ΔR_{ON}.

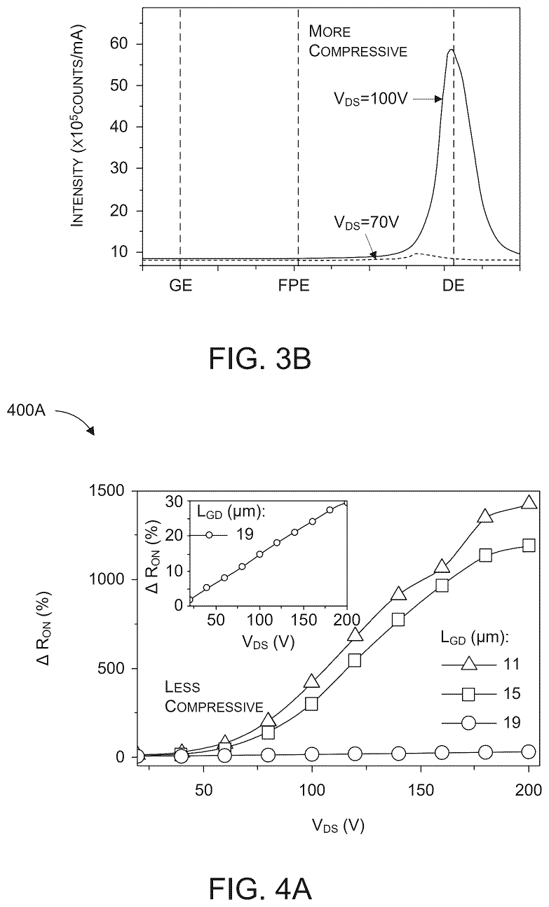

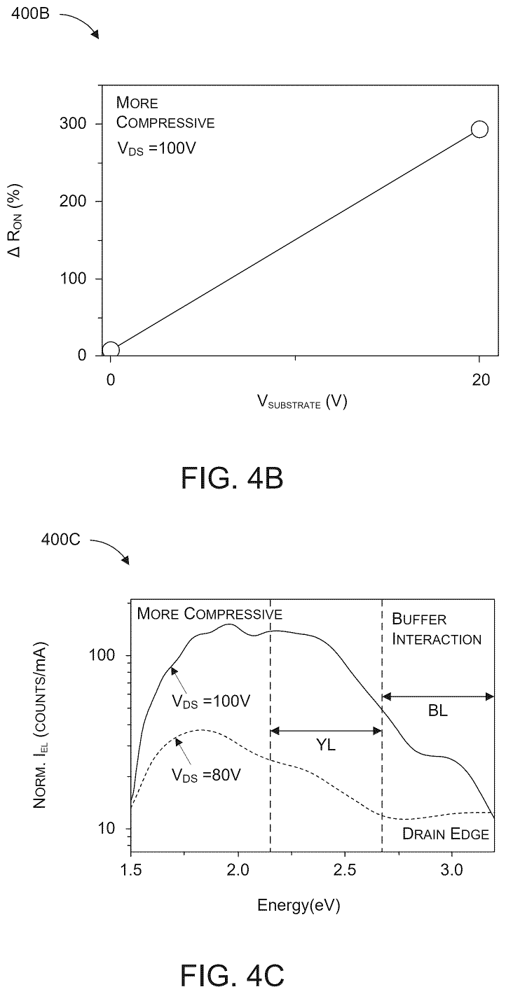

Referring to FIG. 4(A), exemplary representation (400A) of the dynamic R_{ON} characteristics is disclosed as a function of gate-to-drain distance (L_{GD}) for device with less compressive stress transfer layer 116. Dynamic R_{ON} shows a distinct dependence on L_{GD} exhibiting an increase as the L_{GD} is reduced from 19 μm to 11 μm. The observed improvement in Dynamic R_{ON} with an increase in L_{GD} suggests electron trapping to be the dominant mechanism in determining the dynamic R_{ON} of the device with less compressive stress transfer layer 116.

Higher Electric field near the edge of the drain contact 114 in device with more compressive stress transfer layer 116 leads to an injection of holes in the buffer layer 104 which then neutralize the ionized acceptor traps in buffer layer 104 and thereby, reduces the ΔR_{ON}. FIG. 4(B) describes the dynamic R_{ON} characteristics as a function of substrate bias (V_{sub}) for device with more compressive stress transfer layer 116 for V_{DS} of 100V in OFF state. A Positive V_{sub} may enhance electron injection into the buffer layer 104 and oppose the hole injection process. FIG. 4(B) shows exemplary representation (400B) of an increase in ΔR_{ON} of device for a V_{sub} of +20V as compared to that for a V_{sub} of 0 V. This may validate the process of hole injection from the drain contact 114 edge for device 100 with more compressive stress transfer layer 116.

Referring to FIG. 4(C) illustrates exemplary representation (400C) that describes the evolution of EL spectra collected from the drain contact 114 edge for device with more compressive stress transfer layer 116. The HEMT device 100 was stressed in the semi-ON state with V_{DS}=80V, 100V, and I_{D}=20 mA/mm. Therefore, the HEMT device 100 device shows defect transition-assisted distinct yellow (YL) and blue (BL) luminescence peaks near the edge of the drain contact 114. These peaks may be a signature of hot electron interaction with the C-doping induced defects in buffer layer 104 which may further validate the fact that the presence of a high field near the edge of the drain contact 114 may lead to modulation of buffer layer 104 traps and subsequent hole injection in the buffer layer 104 of the HEMT 100 with more compressive stress transfer layer 116.

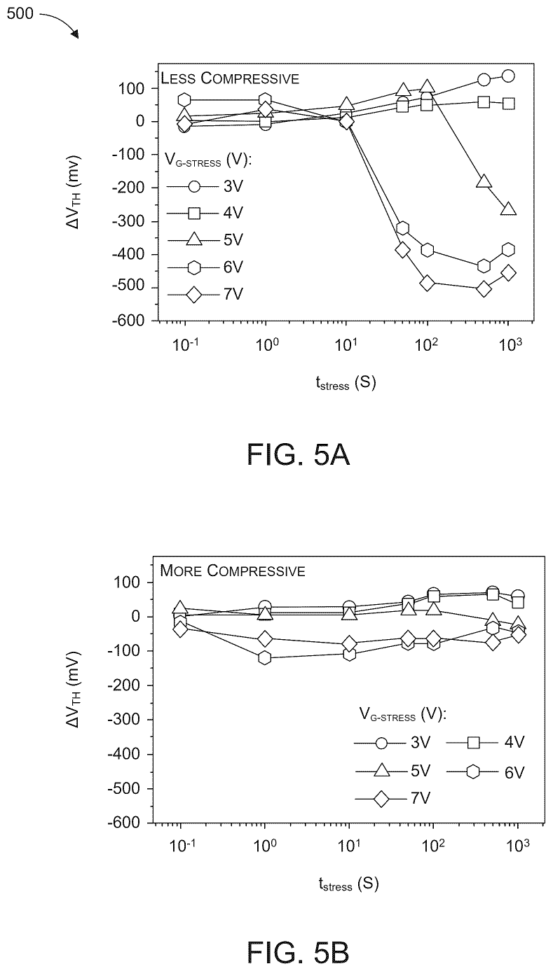

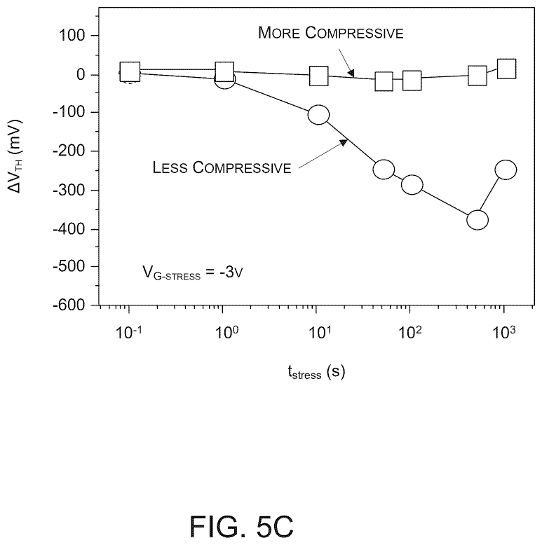

Referring to FIGS. 5(A-B), the exemplary representation 500 of the experimental threshold voltage drifts in response to the accumulated stress time for ON state gate stress for FIG. 5(A) for HEMT device 100 with less compressive stress transfer layer 116 and FIG. 5(B) for HEMT device 100 with more compressive stress transfer layer 116 are disclosed. HEMT device 100 with more compressive stress transfer layer 116 shows a relatively stable threshold voltage in response to ON state gate stress as compared to devices with less compressive stress transfer layer 116. The higher stability of V_{TH} in HEMT device 100 with more compressive stress transfer layer 116 than HEMT with less compressive stress transfer layer 116 under ON state gate stress may be disclosed where the magnitude of the V_{TH} Shift is observed to be a direct function of the gate stress voltage and stress time. While devices with less compressive stress transfer layer 116 may show a gate stress voltage and stress time-dependent shift in V_{TH}, devices with more compressive stress transfer layer 116 on the other hand, are observed to have V_{TH} relatively independent of both. The magnitude of V_{TH} shift in HEMT device 100 with more compressive stress transfer layer 116 never exceeds 100 mV, even for a stress voltage of 7V which may establish the superiority of the HEMT device 100 with higher compressive stress in stress transfer layer 116 in terms of gate reliability.

Referring to FIG. 5(C), the exemplary representation 500 of the comparison of the experimental threshold voltage drifts in response to the accumulated stress time for OFF state gate stress of −3V for HEMT device 100 with less compressive stress transfer layer 116 and more compressive stress transfer layer 116 are disclosed. HEMT device 100 with more compressive stress transfer layer 116 shows a relatively stable threshold voltage in response to OFF state gate stress as compared to devices with less compressive stress transfer layer 116.

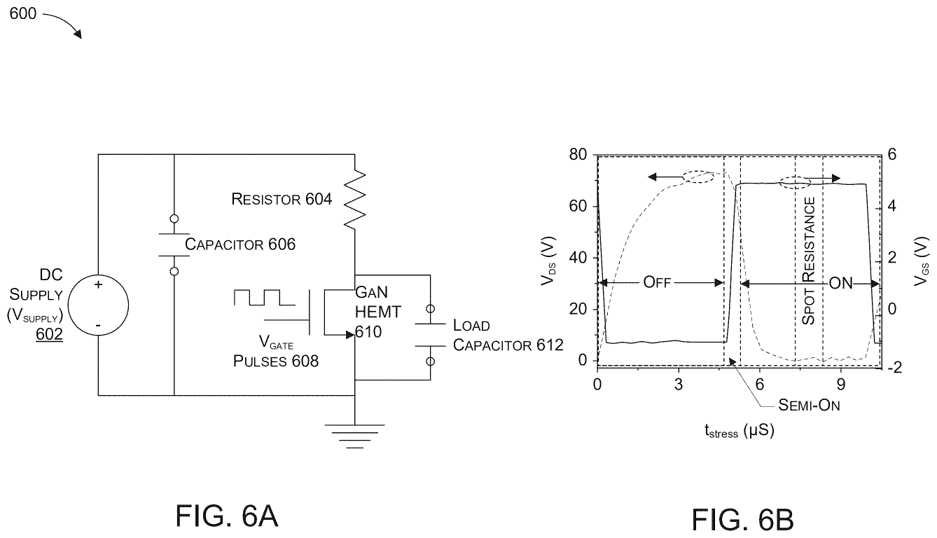

FIGS. 6 (A) to 6 (B) illustrates exemplary implementations 600 of a switching circuit and turn-on transition of the HEMT device through hard switching, in accordance with an embodiment of the present disclosure.

Referring to FIG. 6A, the hard switching circuit may be employed with a series resistor 604 and a load capacitor 612 in parallel with the on-wafer GaN HEMT 100. The entire hard switching circuit on a printed circuit board (except for the on-wafer device) may be mounted on the objective of the microscope to enable on-wafer measurements with minimum parasitic. The measurement procedure, as shown in FIG. 6B may involve pulsing the gate at a specific frequency from OFF (stress) to ON (measurement) state while a fixed DC voltage (V_{supply}) 602 may be applied across the series combination of a resistor 604 and GaN gated HEMT 610. FIG. 6B establishes the turn-ON transition of the HEMT devices through hard switching. The evolution of dynamic ON resistance may be then calculated with the help of measured drain voltage and current.

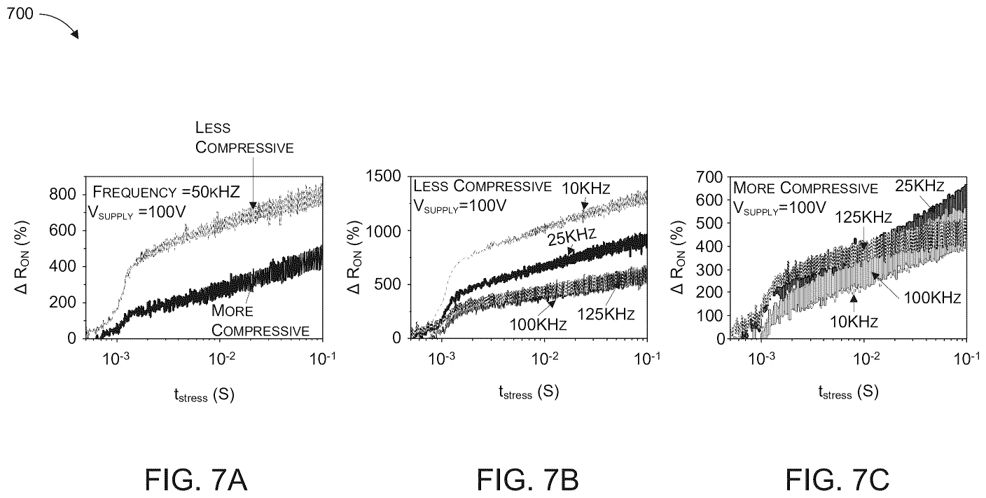

FIGS. 7(A) to 7(C) illustrate exemplary graphical representations 700 of the dynamic R_{ON} of the HEMT device under hard switching stress 100 with more and less compressive mechanical stress in stress transfer layer 116, in accordance with an embodiment of the present disclosure.

Referring to FIG. 7A, a graph illustrates a comparison of the ΔR_{ON} of devices with different mechanical stress in the stress transfer layer 116 under hard switching stress applied by the circuit shown in FIG. 6A. The semiconductor device 100 under test is connected on-wafer between the resistor 604 and ground connection. The gate pulses 608 are applied at different frequencies and the drain voltage is measured across load capacitor 612. FIG. 7A reveals that a higher compressive stress in the stress transfer layer 116 may reduce the dynamic ON resistance significantly. Moreover, device 100 may be tested at different frequencies such that a higher switching frequency may result in more hard switching events while a low frequency would result in longer OFF-state stress. For V_{supply} 602 of 100V, the ΔR_{ON} decreases as the frequency can be increased for devices with less compressive stress transfer layer 116 as shown in FIG. 7B, thereby suggesting a dominant role of OFF-state stress. On the other hand, ΔR_{ON} for the device 100 with the more compressive stress transfer layer 116 shows a negligible dependence on frequency as shown in FIG. 7C.

Further, increasing the compressive stress in the stress transfer layer 116 shifts the field peak from the edge of the gate field plate 118 to the edge of the drain contact 114 thereby mitigating the trapping near the edge of gate field plate 118 and reducing the ΔR_{ON} and its field dependence. Additionally, the field peak at the edge of drain contact 114 leads to the impact ionization followed by the neutralization of ionized buffer traps by the generated holes. The neutralization of ionized buffer traps is seen to govern the frequency-independent and reduced ΔR_{ON} behavior for more compressive stress transfer layer 116 devices under hard switching stress. Comparison of ΔR_{ON} for both the devices therefore establishes that device 100 with more compressive stress transfer layer 116 may show improved performance under hard switching stress and shows less dependence on the switching frequency. This kind of behaviour is desirable for increasing the switching frequency of power converters.

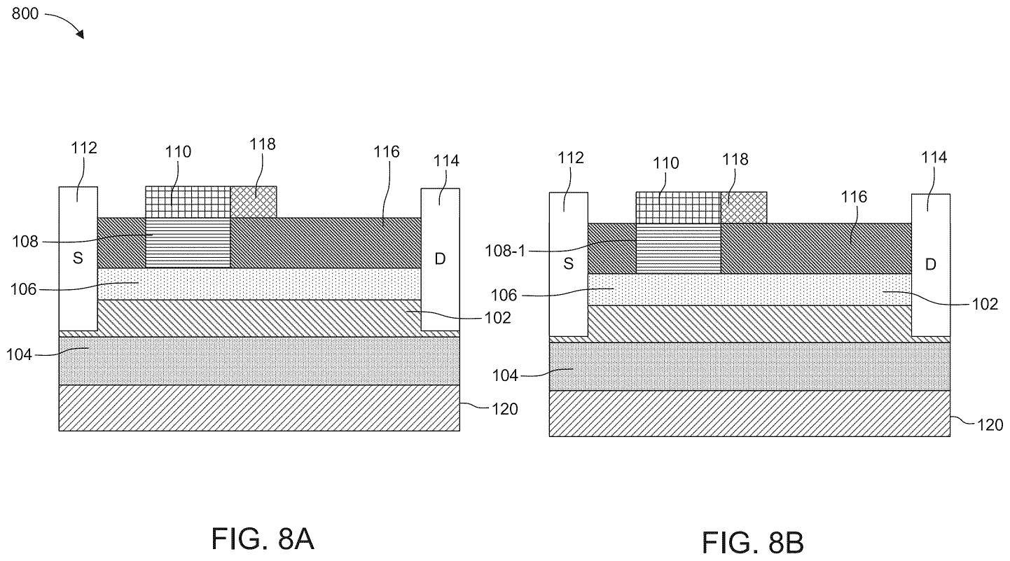

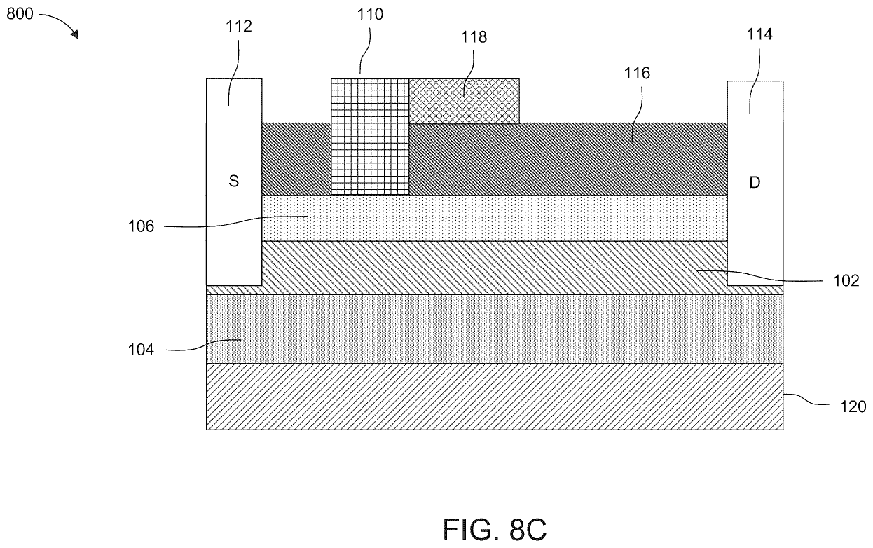

FIGS. 8 (A-C) illustrates an exemplary representation 800 of the design variations in the gate stack of the HEMT 100, in accordance with an embodiment of the present disclosure.

Referring to FIG. 8 (A-C), the gate structure may include a metal layer 110 and another layer 108 sandwiched between barrier layer 106 and gate metal layer 110 which may include a p-type gallium nitride (p GaN) or any p-type oxide like copper oxide (CuO), Nickel oxide (NiO), the semiconductor device that includes a gate dielectric layer 108-1 like Silicon oxide (SiOₓ), Silicon nitride (SiNₓ), Aluminium oxide (AlOₓ) or any combination thereof, the semiconductor device 100 may also exclude any p-type layer or dielectric layer 108-1 in the gate structure in accordance with an embodiment of the present disclosure.

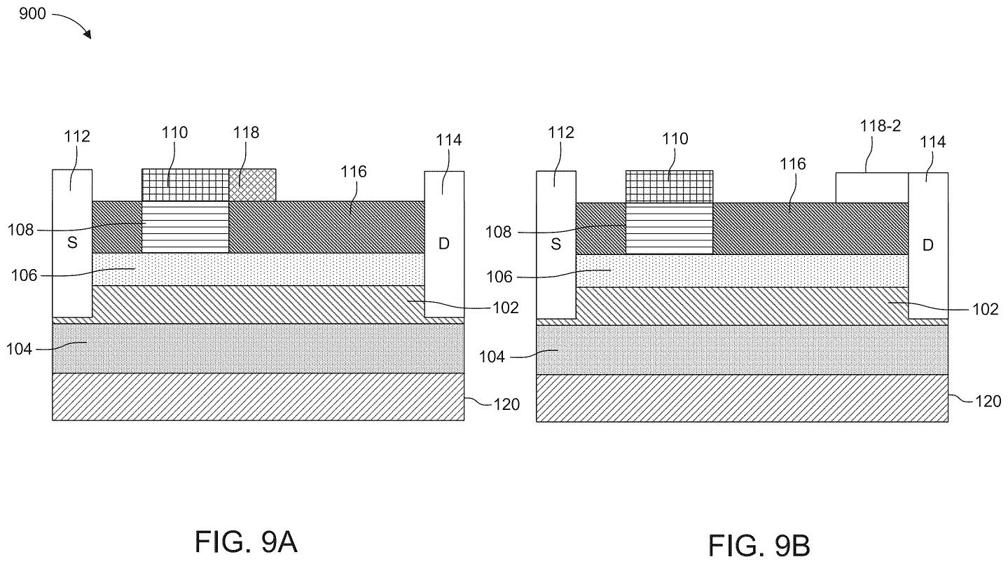

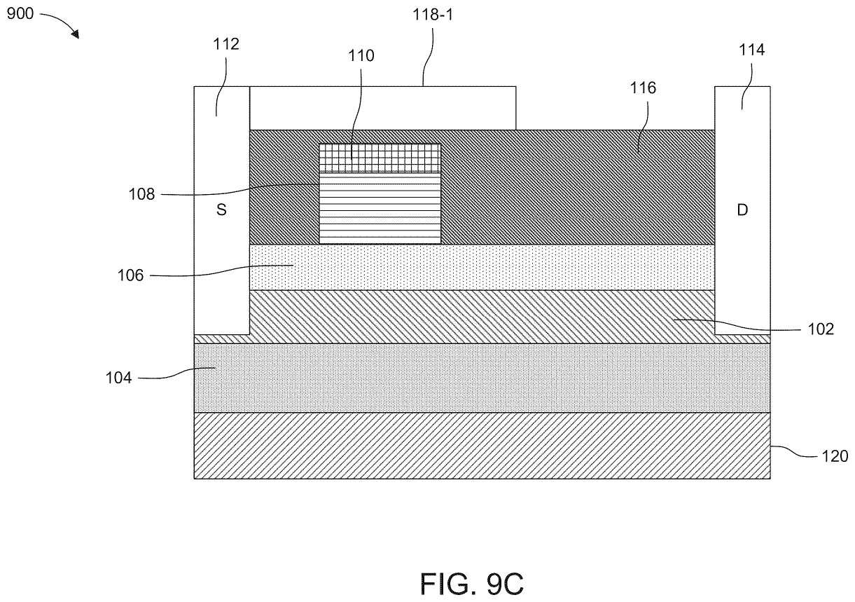

FIGS. 9 (A-C) illustrates an exemplary representation 900 of the design variations of the field plate in the semiconductor device, in accordance with an embodiment of the present disclosure.

Referring to FIG. 9 (A-C), the semiconductor device 100 may include a field plate connected to gate metal layer 110 referred as Gate field plate 118 (A), or connected to drain contact 114 referred as the drain field plate 118-2 (B), or connected to source contact 112 referred as source field plate 118-1 (C) or may be any combination of these designs, in accordance with an embodiment of the present disclosure. The field plate configurations may redistribute the channel electric field to improve the device performance and reliability further.

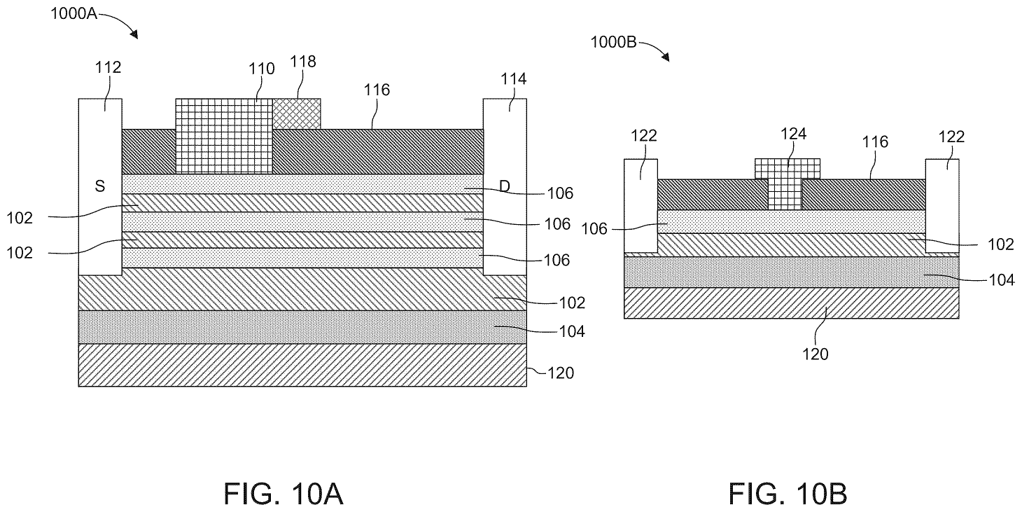

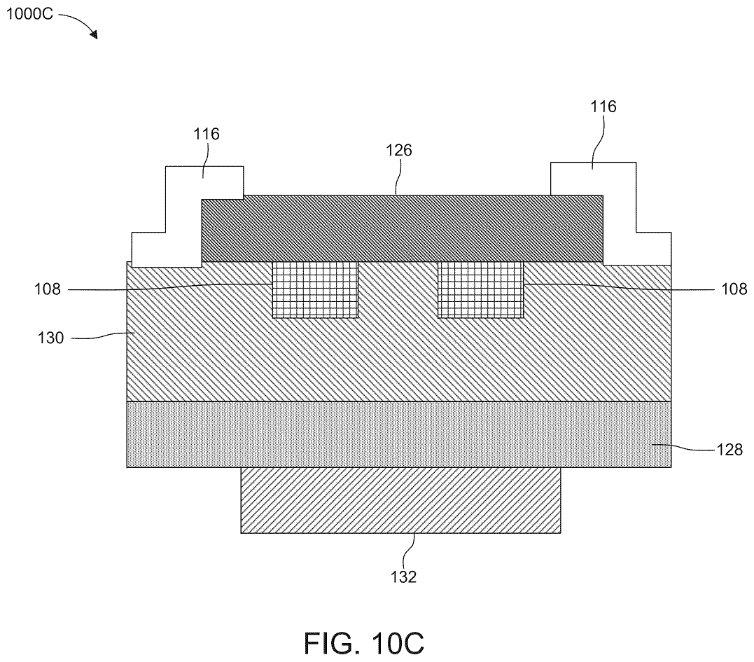

FIG. 10 (A) illustrates an exemplary representation of the Multi-channel HEMT 1000A wherein the stress transfer layer 116 may be disposed between source contact 112 and drain contact 114. Multi-channel HEMTs 1000A can contain several barrier layer 106/channel layer 102 stacks to get high 2DEG density. Using the stress transfer layer 116 in the structure of the multi-channel HEMT 1000A can improve the reliability and performance of the device 100, in accordance with an embodiment of the present disclosure.

FIG. 10 (B) illustrates an exemplary representation of the schottky barrier diode 1000B wherein the stress transfer layer 116 is disposed on the barrier layer 106 between the anode contact (A) 124 and the cathode contacts (K) 122. The stress transfer layer 116 can lead to better electric field distribution in the channel layer 102 and hence enhance the performance metrics like breakdown voltage and improve the device 100 reliability.

FIG. 10(C) illustrates an exemplary representation of the vertical Schottky junction barrier diode 1000C wherein the Schottky contact metal 126 is disposed on the n⁻ doped GaN layer 130. The stress transfer layer 116 disposed on the n GaN layer 130 can manage the electric field at the corners of the device 100 and minimize the electric field crowding, thus improving the device 100 performance and reliability. Further, n-GaN layer 130 can cover the two p-GaN layers 108 and an ohmic contact 132 can be formed at the bottom part of the n⁺ GaN layer 128.

In such embodiment, the semiconductor device 100 may be applicable to various semiconductor device structures, including but not limited to high-electron-mobility transistors (HEMTs), metal-insulator-semiconductor high-electron-mobility transistors (MISHEMTs), and power electronic devices. The controlled stress engineering in the stress transfer layer 116 may contribute to improved robustness, reliability, and enhanced high-power performance in such devices.

While considerable emphasis has been placed herein on the particular features of this disclosure, it will be appreciated that various modifications may be made and that many changes may be made in the preferred embodiments without departing from the principles of the disclosure. These and other modifications in the nature of the disclosure or the preferred embodiments will be apparent to those skilled in the art from the disclosure herein, whereby it is to be distinctly understood that the foregoing descriptive matter is to be interpreted merely as illustrative of the disclosure and not as a limitation.

The embodiments herein and the various features and advantageous details thereof are explained with reference to the non-limiting embodiments in the description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the embodiments as described herein.

Throughout this specification the word “comprises”, or variations such as “comprises” or “comprising”, will be understood to imply the inclusion of a stated element, integer or step, or group of elements, integers or steps, but not the exclusion of any other element, integer or step, or group of elements, integers or steps.

The use of the expression “at least” or “at least one” suggests the use of one or more elements or ingredients or quantities, as the use may be in the embodiment of the disclosure to achieve one or more of the desired objects or results.

### ADVANTAGES OF THE PRESENT DISCLOSURE

The proposed disclosure provides a system and a method that provides a semiconductor device with a stress transfer layer whose mechanical stress has been engineered for enhanced performance and improved device reliability.

The proposed disclosure provides a device and a method that includes intrinsic mechanical stress in the stress transfer layer as a control parameter to improve the performance and reliability of HEMT. With higher compressive stress in the stress transfer layer, threshold voltage of the device is enhanced. Additionally, the threshold voltage stability under ON and OFF state gate stress improves as the compressive stress in the stress transfer layer increases.

The proposed disclosure provides a system and a method to optimize electric field distribution by reducing peak field concentrations near the gate and gate field plate region, thereby enhancing the OFF-state device breakdown voltage.

The present disclosure uses a compressive stress transfer layer to reduce the dynamic ON resistance of the device under DC and pulsed OFF state and semi-ON state stress, thereby, enhancing the device reliability and robustness.

The present disclosure provides a stress transfer layer wherein an increase in the compressive mechanical stress reduces the dynamic ON resistance under hard switching stress and makes the dynamic ON resistance independent of switching frequency.

The present disclosure aims at achieving multiple improvements in the device with a simple stress transfer layer design proposal, thereby minimizing the processing complexity while being cost effective.

We claim:

1. A semiconductor device (100) comprising:
a substrate (120);
a buffer layer (104) formed on the substrate (120), wherein the buffer layer (104) is doped with at least one type of dopant selected from any or a combination of a carbon, iron, or a carbon and iron co-doping.
an unintentionally doped (UID) Gallium nitride (GaN) channel layer (102) positioned on the buffer layer (104);
a barrier layer (106) formed on the UID channel layer (102); and
a stress transfer layer (116) configured with a tunable intrinsic compressive mechanical stress being deposited on barrier layer (106) for improved device (100) performance and reliability.

2. The semiconductor device (100) as claimed in claim 1, wherein the stress transfer layer (116) transfers the mechanical stress to the adjacent layers while passivating the surface underneath.

3. The semiconductor device (100) as claimed in claim 1, wherein the stress transfer layer (116) is made of a dielectric material of any stoichiometry selected from any or a combination of Silicon oxide (SiOₓ), Silicon nitride (SiNₓ), aluminium oxide (AlOₓ), Hafnium oxide (HfOₓ), zirconium oxide (ZrOₓ), Titanium oxide (TiOₓ), Tantalum oxide (TaOₓ), any p-type oxide like Nickel oxide (NiOₓ), and copper oxide (CuO), and wherein the intrinsic stress in the stress transfer layer (116) is tuned by varying a set of deposition parameters selected from any or a combination of gas flow rate, deposition pressure, deposition power, deposition temperature in the inductively coupled plasma chemical vapor deposition (ICPCVD), and plasma enhanced chemical vapor deposition (PECVD) of the stress transfer layer (116).

4. The semiconductor device (100) as claimed in claim 1, wherein the stress transfer layer is deposited using a set of techniques selected from any or a combination of inductively coupled plasma chemical vapor deposition (ICPCVD), plasma enhanced chemical vapor deposition (PECVD), Atomic layer deposition (ALD), Sputtering and Evaporation.

5. The semiconductor device (100) as claimed in claim 1 wherein the semiconductor device (100) further comprising a gate structure wherein:
the gate structure comprises a material selected from any or a combination of p-type material having p-type GaN layer (p-GaN) (108) or any p-type oxide (108) like Nickel oxide (NiO), Titanium oxide (TiO) or dielectric material (108-1), Aluminium oxide (AlOₓ), Silicon oxide (SiOₓ), and Silicon Nitride (SiNₓ); and
the metal layer (110) comprises a material selected from any or a combination of titanium (Ti), titanium nitride (TiN), tungsten (W), tantalum (Ta), tantalum nitride (TaN), molybdenum (Mo) Scandium (Sc), Nickel (Ni), Chromium (Cr), and Gold (Au).

6. The semiconductor device (100) as claimed in claim 1, wherein the semiconductor device (100) is a GaN based heterostructure comprising any of High-Electron-Mobility Transistor (HEMT), Multi-channel HEMTs, Fin channel HEMTs, Metal Insulator Semiconductor High-Electron-Mobility Transistor (MIS-HEMTs), Gate injection transistors, Schottky Barrier Diode, Junction Barrier Diode, Fin diodes, multi-channel diodes and monolithic integrated AlGaN/GaN heterostructure.

7. The semiconductor device (100) as claimed in claim 1, wherein the semiconductor device (100) further comprises:
a source contact (112) and a drain contact (114) formed on the GaN channel layer (102); and
a field plate (FP) comprising of the metal layer coupled to the gate metal layer (110) (gate field plate 118), the drain contact (114) (drain field plate 118-2), the source contact (112) (source field plate 118-1) or any combination thereof.

8. The semiconductor device (100) as claimed in claim 1, wherein:
the substrate (120) is made of a material selected from any or a combination of Silicon (Si), Silicon Carbide (SiC), diamond, sapphire, and Qromis substrate technology (QST); and
the barrier layer (106) comprises a material selected from any or a combination of an aluminium gallium nitride (AlGaN), Indium nitride (InN), Indium aluminium nitride (InAlN), aluminium nitride (AlN).

9. A method (100B) of fabricating a semiconductor device (100), the method (100B) comprising:
depositing (302) a gate structure having a gate metal layer (110), wherein the gate metal layer (110) comprises titanium (Ti) or titanium nitride (TiN); and performing (302) self-aligned etching of a gate dielectric layer 108-1 or a p-GaN layer 108 using the Ti/TiN gate structure (110) and enabling the gate dielectric layer 108-1 or the p-GaN layer 108 positioned on a AlGaN barrier layer (106), and a Ti/TiN gate metal layer (110) positioned on the gate dielectric layer 108-1 or the p-GaN layer 108;
performing (304) Mesa etching to provide isolation between individual devices;
forming (306), ohmic contacts on a source contact (112) and a drain contact (114) by depositing a metal stack, wherein the metal stack comprising of one or more metal stacks selected from any or a combination of titanium (Ti), tantalum (Ta), a titanium nitride (TiN), aluminium (Al), nickel (Ni), Platinum (Pt), Palladium (Pd), molybdenum (Mo), chromium (Cr), and gold (Au) followed by annealing process;
depositing (308) a stress transfer layer using a chemical vapor deposition (CVD) technique with intrinsic mechanical stress being tuned by a set of chemical vapor deposition parameters;
etching (310) to open the stress transfer layer (116) for establishing electrical connections; and
thickening (312) the source contact (112) and the drain contact (114) metal contacts by metal deposition along with formation of field plates, followed by the annealing process.
